(19) United States
(12) Patent Application Publication
(10) Pub. No.: US 2026/0354121 A1
(43) Pub. Date: Nov. 5, 2026

(54) ADHESIVE TAPE SHEETS, AND METHOD OF MANUFACTURING SEMICONDUCTOR DEVICES USING THE SAME

(71) Applicant: Samsung Electronics Co., Ltd., Suwon-si (KR)

(72) Inventor: Hyungjun Kim, Suwon-si (KR)

(21) Appl. No.: 19/635,093

(22) Filed: Mar. 31, 2026

(30) Foreign Application Priority Data
Apr. 30, 2025 (KR) 10-2025-0057022

(51) Int. Cl. H10P 74/00; C09J 11/04; C09J 11/08; H10P 58/00; H10P 72/70; H10P 74/20; H10W 80/00

(52) U.S. Cl. CPC H10P 74/232; C09J 11/04; C09J 11/08; H10P 58/20; H10P 72/7404; H10P 74/207; H10W 80/312; H10W 80/327

(57) ABSTRACT

A method of manufacturing a semiconductor device includes sorting a plurality of semiconductor chips into a plurality of grades by performing a wafer test on a wafer on which the plurality of semiconductor chips are formed, the plurality of semiconductor chips including first semiconductor chips of a first grade; transferring each of the first semiconductor chips onto an adhesive tape sheet; and separating the first semiconductor chips from the adhesive tape sheet and stacking the first semiconductor chips in order on a base wafer. The adhesive tape sheet includes a thixotropic adhesive layer including a polymer composition including a thixotropic agent.

### CROSS-REFERENCE TO RELATED APPLICATIONS

This application claims the benefit of priority under 35 U.S.C. §119 to Korean Patent Application No. 10-2025-0057022 filed on Apr. 30, 2025 in the Korean Intellectual Property Office, the disclosure of which is incorporated herein by reference in its entirety.

### TECHNICAL FIELD

The present disclosure relates to an adhesive tape sheet and a method of manufacturing a semiconductor device using the same.

### BACKGROUND

As electronic devices have been designed to have a reduced weight and high performance, research and development of semiconductor devices designed to be miniaturized and to have high performance and high reliability have been continuously conducted. To meet the above demands, research and development of an adhesive tape sheet which may enable precise handling of a semiconductor chip have also been continuously conducted.

### SUMMARY

Some example implementations of the present disclosure is to provide an adhesive tape sheet having thixotropic properties and a method of manufacturing a semiconductor device using the same.

According to some example implementations of the present disclosure, a method of manufacturing a semiconductor device includes forming a plurality of semiconductor chips on a wafer; sorting the plurality of semiconductor chips into first and second semiconductor chips by performing a wafer test on the wafer, providing first and second adhesive tape sheets, transferring the first semiconductor chip to the first adhesive tape sheet, and transferring the second semiconductor chip to the second adhesive tape sheet; and providing first and second base wafers, separating the first semiconductor chip from the first adhesive tape sheet and forming the first semiconductor chip on the first base wafer, and separating the second semiconductor chip from the second adhesive tape sheet and forming the second semiconductor chip on the second base wafer, wherein each of the first and second adhesive tape sheets includes an adhesive layer, wherein the adhesive layer includes a first portion to which a corresponding semiconductor chip is attached; and a second portion surrounding the first portion and to which a support structure is attached, wherein the first portion includes a polymer composition including a thixotropic agent, and wherein adhesive force of the second portion is greater than adhesive force of the first portion.

According to some example implementations of the present disclosure, a method of manufacturing a semiconductor device includes forming a plurality of semiconductor chips on a wafer; sorting the plurality of semiconductor chips into first and second semiconductor chip groups by performing a wafer test on the wafer; providing first and second adhesive tape sheets, transferring the first semiconductor chip group to the first adhesive tape sheet, and transferring the second semiconductor chip group to the second adhesive tape sheet; and providing first and second base wafers, separating first semiconductor chips of the first semiconductor chip group from the first adhesive tape sheet and stacking the first semiconductor chips in order on the first base wafer, and separating second semiconductor chips of the second semiconductor chip group from the second adhesive tape sheet and stacking the second semiconductor chips in order on the second base wafer, wherein each of the first and second adhesive tape sheets includes an adhesive layer including a polymer composition including a thixotropic agent.

According to some example implementations of the present disclosure, a method of manufacturing a semiconductor device includes sorting a plurality of semiconductor chips into a plurality of grades by performing a wafer test on a wafer on which the plurality of semiconductor chips are formed, the plurality of semiconductor chips including first semiconductor chips of a first grade; transferring each of the first semiconductor chips onto an adhesive tape sheet; and separating the first semiconductor chips from the adhesive tape sheet and stacking the first semiconductor chips in order on a base wafer, wherein the adhesive tape sheet includes a thixotropic adhesive layer including a polymer composition including a thixotropic agent, and wherein a weight ration of the thixotropic agent relative to the polymer composition is in a range of about 1 wt(%) to about 5 wt(%).

### BRIEF DESCRIPTION OF DRAWINGS

The above and other aspects, features, and advantages of the present disclosure will be more clearly understood from the following detailed description, taken in combination with the accompanying drawings.

FIG. 1 is a vertical cross-sectional diagram illustrating an adhesive tape sheet according to some example implementations of the present disclosure.

FIG. 2 is a plan diagram illustrating an adhesive tape sheet according to some example implementations of the present disclosure.

FIG. 3 is a plan diagram illustrating an adhesive tape sheet according to some example implementations of the present disclosure.

FIG. 4A is a plan diagram illustrating an adhesive tape sheet according to some example implementations of the present disclosure.

FIG. 4B is a cross-sectional diagram taken along line I-I’ in FIG. 4A.

FIG. 5A is a plan diagram illustrating an adhesive tape sheet according to some example implementations of the present disclosure.

FIG. 5B is a cross-sectional diagram taken along line I-I’ in FIG. 5A.

FIG. 6 is a plan diagram illustrating an adhesive tape sheet according to some example implementations of the present disclosure.

FIG. 7 is a flowchart illustrating processes of a method of manufacturing a semiconductor device using an adhesive tape sheet in order according to some example implementations of the present disclosure.

FIGS. 8, 9, 10, 11A, 11B, 11C, 12, 13, 14A, 14B, and 14C are vertical cross-sectional diagrams illustrating a method of manufacturing a semiconductor device using an adhesive tape sheet according to some example implementations of the present disclosure.

FIG. 15A is a perspective diagram illustrating a semiconductor device according to some example implementations of the present disclosure.

FIG. 15B is a cross-sectional diagram taken along line II-II’ in FIG. 15A.

FIG. 15C is an enlarged diagram illustrating region “A” in FIG. 15B.

FIG. 16A is a perspective diagram illustrating a semiconductor device according to some example implementations of the present disclosure.

FIG. 16B is a cross-sectional diagram taken along line III-III’ in FIG. 16A.

FIG. 16C is an enlarged diagram illustrating region “B” in FIG. 16B.

FIG. 17 is a perspective diagram illustrating a semiconductor device according to some example implementations of the present disclosure.

FIG. 18A is a perspective diagram illustrating a semiconductor device according to some example implementations of the present disclosure.

FIG. 18B is a cross-sectional diagram taken along line IV-IV’ in FIG. 18A.

### DETAILED DESCRIPTION

Hereinafter, implementations of the present disclosure will be described as follows with reference to the accompanying drawings.

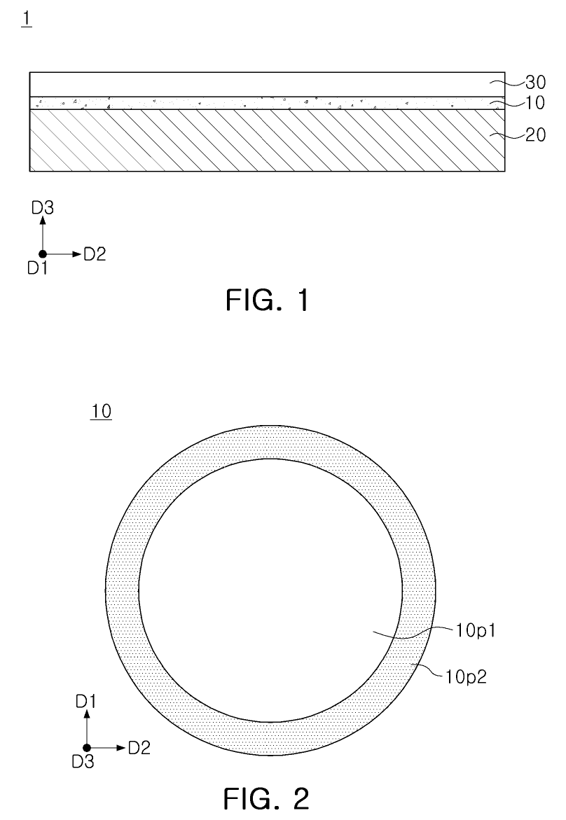

FIG. 1 is a cross-sectional diagram illustrating an adhesive tape sheet 1 according to some example implementations.

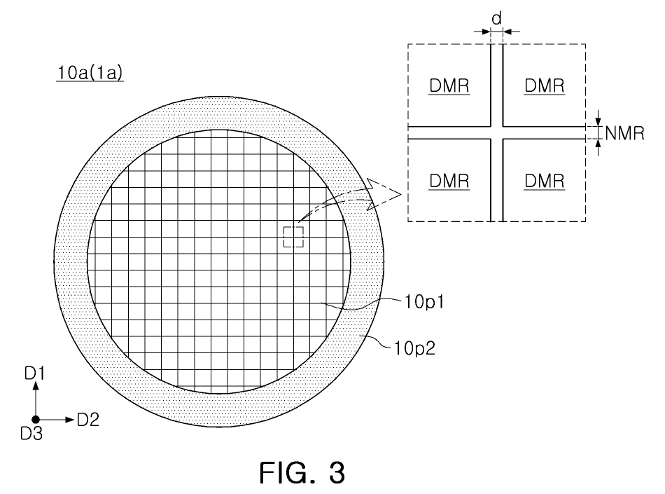

FIG. 2 is a plan diagram illustrating an adhesive tape sheet according to some example implementations, illustrating an adhesive layer 10 of the adhesive tape sheet 1 in FIG. 1.

Referring to FIG. 1, an adhesive tape sheet 1 may include a base layer 20, an adhesive layer 10 on the base layer 20, and a cover layer 30 on the adhesive layer 10. The base layer may be referred to as a base film, the adhesive layer may be referred to as an adhesive film, and the cover layer may be referred to as a cover film.

In example implementations, the adhesive tape sheet 1 may protect or support an adherend which may be temporarily attached thereto. The adhesive tape sheet 1 may be a tape sheet used in a semiconductor process, but some example implementations thereof is not limited thereto. When the adhesive tape sheet 1 is used in the semiconductor process, the adherend may include semiconductor chips 100C1, 100C2, and 100C3 (e.g., ‘100C1’ in FIG. 14A, ‘100C2’ in FIG. 14B, and ‘100C3’ in FIG. 14C). Hereinafter, for ease of description, the example in which the adhesive tape sheet 1 is used in a semiconductor process is taken for illustration.

An adherend may be temporarily attached to the adhesive layer 10, and the adhesive layer 10 may protect or support the adherend. In example implementations, adherends sorted to the same grade through a predetermined test may be temporarily attached to the adhesive layer 10. In example implementations, the adherends may include semiconductor chips (e.g., ‘100C1’ in FIG. 14A, ‘100C2’ in FIG. 14B, and ‘100C3’ in FIG. 14C).

The adhesive layer 10 may include a polymer composition and an additive added to the polymer composition. The additive may include a thixotropic agent for controlling flow properties of the adhesive layer 10.

The thixotropic agent in the example implementations may include an oil-based thixotropic agent and an aqueous (i.e., water-based) thixotropic agent, and the polymer composition may be selected depending on characteristics of the thixotropic agent.

The oil-based thixotropic agent in the example implementations may include an inorganic, organic, or composite thixotropic agent. The inorganic thixotropic agent may be selected from a group including fumed silica, bentonite, ultrafine precipitated calcium carbonate (PCC), or synthetic aluminum silicate hexahydrate. The organic thixotropic agent may be selected from a group including metal soap, hydrogenated castor oil, polyamide wax, oxidized polyethylene, vegetable oil, or linseed oil. The composite thixotropic agent may be selected from a group including organic bentonite or surface-treated calcium carbonate.

When the oil-based thixotropic agent is added, the polymer composition may be selected from a group including silicone polymer, propylene polymer, ethylene polymer, styrene polymer, urethane polymer, or ester polymer.

The aqueous thixotropic agent in the example implementations may include an inorganic agent, organic agent, or composite thixotropic agent.

The inorganic thixotropic agent may be at least one or more selected from a group including synthetic silica or bentonite. The synthetic silica may include, for example, a water-soluble alkali silicate. The organic thixotropic agent may be at least one or more selected from a group including cellulose derivatives, casein, polyvinyl, polyacrylic acid, or anhydrous maleic acid copolymers. The cellulose derivatives may include, for example, hydroxyethyl cellulose (hec) and hydroxypropyl cellulose. The composite thixotropic agent may include organic bentonite.

When the aqueous thixotropic agent is added, the polymer composition may be selected from a group including a vinyl alcohol polymer, an acrylic polymer, or a urethane polymer.

In the adhesive layer 10 in the example implementations, the additive may be included in a weight ratio of about 5.0 wt(%) or less relative to the polymer composition. In some example implementations, the additive may be included in a weight ratio of about 1.0 wt(%) to about 5.0 wt(%) relative to the polymer composition. In some example implementations, the additive may be included in a weight ratio of about 3.0 wt(%) to about 5.0 wt(%) relative to the polymer composition. In example implementations, the weight ratio may indicate a ratio of the weight of the additive to the weight of the polymer composition.

In example implementations, when the weight ratio is less than about 1.0 wt(%), the semiconductor chip was detached from the adhesive tape sheet or that residue of the adhesive layer remained between the connection pads when the semiconductor chip was picked up.

In example implementations, when the weight ratio is greater than about 5.0 wt(%), the adhesive layer was excessively stretched when the semiconductor chip was picked up or that the semiconductor chip could not be easily separated, such that damage occurred to the semiconductor chip or it was not easy to pick the semiconductor chip up.

In some example implementations, the adhesive layer 10 may include a non-UV adhesive composition not cured by ultraviolet (UV) ray. In another aspect, the adhesive layer 10 may include an adhesive component which may have properties of not being cured or crosslinked in response to ultraviolet rays, and of which adhesive force or physical properties do not change when ultraviolet rays are irradiated thereto. In another aspect, the adhesive layer 10 may not include a generally used ultraviolet-curable acrylic adhesive, an ultraviolet-sensitive urethane adhesive, or a photosensitive resin including a photoinitiator.

According to the present disclosure, as the adhesive layer 10 includes a non-ultraviolet-type adhesive composition, an issue which may occur due to partially curing of the adhesive layer 10 by ultraviolet rays may be reduced or prevented. In example implementations, the issue may include a semiconductor chip being not properly picked up from an adhesive tape sheet and a residue remaining between connection pads of the semiconductor chip even when the semiconductor chip is separated.

In some example implementations, the adhesive layer 10 (or, the adhesive tape sheet 1) may be reused after the semiconductor process is performed.

In some example implementations, the thickness of the adhesive layer 10 may be about 100 μm or less. In some example implementations, a thickness of the adhesive layer 10 may be in a range of about 10 μm or more and about 100 μm or less. In some example implementations, the thickness of the adhesive layer 10 may be in a range of about 10 μm or more and about 50 μm or less.

The adhesive layer 10 may include a first portion 10p1 to which the adherends are attached and a second portion 10p2 to which a support structure (e.g., ‘RF’ in FIG. 11A) is attached. In example implementations, the support structure RF may include a ring frame stably supporting the adherends by fixing the adhesive tape sheet (‘1S’ in FIG. 11A).

The first portion 10p1 may include a central portion of the adhesive layer 10 and may be a region to which the adherends are temporarily attached.

The second portion 10p2 may include an edge region of the adhesive layer 10 and may be a region to which the support structure is attached. In a planar view, the second portion 10p2 may be formed to surround the first portion 10p1.

The adhesive force of the second portion 10p2 may be greater than the adhesive force of the first portion 10p1, which may be for the support structure to support the adherends stably. The adhesive force of the first portion 10p1 may be provided by the polymer composition including the thixotropic agent. The adhesive force of the second portion 10p2 may be provided by applying an adhesive having an adhesive force to the edge region of the adhesive layer 10. A material of the adhesive is not limited as long as the adhesive force thereof is greater than the adhesive force of the first portion 10p1.

The base layer 20 may be a support disposed on one surface of the adhesive layer 10 and supporting the adhesive layer 10. The base layer 20 may provide structural stability of the adhesive layer 10. The base layer 20 may provide stability which may maintain the physical form of the adhesive layer 10 and may withstand mechanical force applied from the outside, for example. The base layer 20 may provide thermal and chemical resistance to withstand various environmental conditions of the semiconductor process.

The base layer 20 may include a material suitable for the above-described purpose. The base layer 20 may include a material having excellent flexibility, chemical resistance, and heat resistance. The base layer 20 may include, for example, one of polyimide (PI), polyester (PET), polyurethane (PU), polyvinyl chloride (PVC), or polyolefin (PO).

The thickness of the base layer 20 may be about 100 μm or less. In some example implementations, the thickness of the base layer 20 may be in a range of about 25 μm or more and about 100 μm or less. In some example implementations, the thickness of the base layer 20 may be in a range of about 50 μm or more and about 100 μm or less.

The cover layer 30 may be a covering film disposed on the other surface opposite to the one surface of the adhesive layer 10 and covering the other surface of the adhesive layer 10. The cover layer 30 may protect the adhesive layer 10 from being in contact with the external environment. The cover layer 30 may protect the adhesive layer 10 from, for example, dust, contaminants, moisture, or the like.

The cover layer 30 may include a material suitable for the above-described purpose. The cover layer 30 may include a material having excellent chemical resistance and heat resistance and being easily separated from the adhesive layer 10. The cover layer 30 may include, for example, polyethylene (PE), polypropylene (PP), polyester (PET), or silicone-treated film.

The thickness of the cover layer 30 may be about 50 μm or less. In some example implementations, the thickness of cover layer 30 may be in a range of about 30 μm or more and about 50 μm or less.

The adhesive tape sheet 1 may be provided in a state in which the cover layer 30 covers the adhesive layer 10. The cover layer 30 may be separated from the adhesive layer 10 such that one surface of the adhesive layer 10 is exposed, and an adherend may be attached to the exposed surface of the adhesive layer 10.

In some example implementations, the adhesive tape sheet 1 may include the base layer 20 and the adhesive layer 10. In other words, the adhesive tape sheet 1 may include the base layer 20 and the adhesive layer 10 without the cover layer 30.

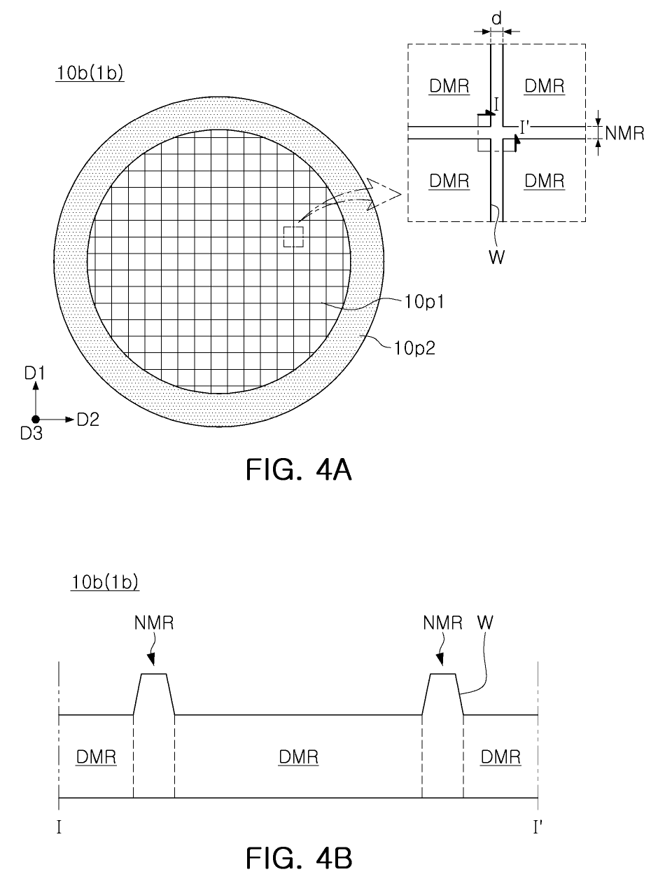

FIG. 3 is a plan diagram illustrating an adhesive tape sheet 1a according to some example implementations, illustrating an adhesive layer 10a of the adhesive tape sheet 1a.

Referring to FIG. 3, the adhesive tape sheet 1a may be the same as or similar to the example described with reference to FIGS. 1 and 2, other than the configuration in which the adhesive layer 10a having adhesive regions DMR and a non-adhesive region NMR is included.

The first portion 10p1 of the adhesive layer 10a may include the adhesive regions DMR to which the adherend is attached and the non-adhesive region NMR to which the adherend is not attached. When the adherend includes a semiconductor chip, the adhesive region DMR may be referred to as a mounting region, and the non-adhesive region NMR may be referred to as a non-mounting region.

The non-adhesive region NMR may be formed by selectively performing laser irradiation or other marking techniques on the first portion 10p1 of the adhesive layer 10a. For example, the marking technique may be performed by providing a visual or physical mark which may demarcate or identify the non-adhesive region NMR on the surface of the first portion 10p1.

The adhesive regions DMR may be distinct from each other by the non-adhesive region NMR, and the adhesive regions DMR may be disposed in a grid shape.

The non-adhesive region NMR may include a portion extending in a first direction D1 and a portion extending in a second direction D2 perpendicular to the first direction. A width d of the non-adhesive region NMR may be in a range of about 50 μm to about 100 μm.

The non-adhesive region NMR may be formed by selectively performing laser irradiation or other marking technique on the first portion 10p1 of the adhesive layer 10a. For example, the marking technique may be performed by providing a visual or physical mark which may demarcate or identify the non-adhesive region NMR on the surface of the first portion 10p1.

Accordingly, the non-adhesive region NMR may work as a reference for position alignment or arrangement of the adherends, and may contribute to assuring positional consistency in which a plurality of adherends may be precisely aligned or fixed. Also, the non-adhesive region NMR may be advantageous in improving the accuracy of a subsequent process (e.g., separation of a semiconductor chip) after the adhesion process.

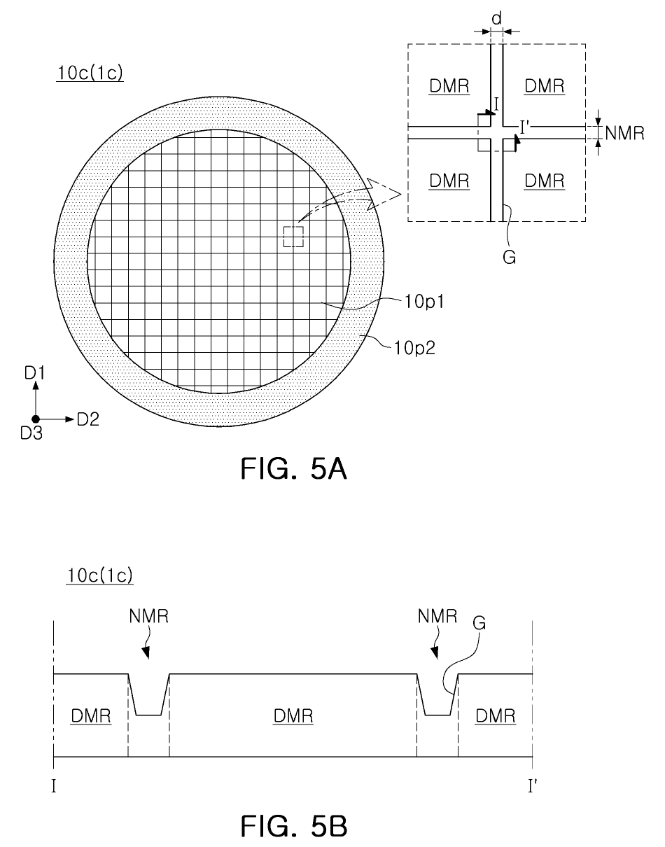

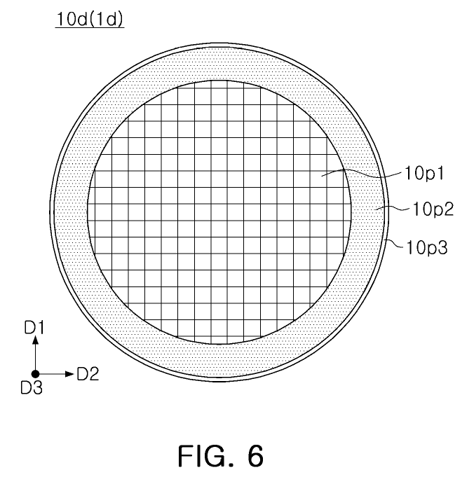

FIG. 4A is a plan diagram illustrating an adhesive tape sheet 1b according to some example implementations, illustrating an adhesive layer 10b of the adhesive tape sheet 1b. FIG. 4B is a cross-sectional diagram taken along line I-I’ in FIG. 4A.

Referring to FIGS. 4A and 4B, the example implementations may be the same as or similar to the example described with reference to FIGS. 1-3, other than the configuration in which the adhesive regions DMR may be separated by the partition wall W.

In the example implementations, the non-adhesive region NMR may be defined by the partition wall W. The partition wall W may protrude in the vertical direction D3 from an upper surface of the first portion 10p1 of the adhesive layer 10b. The upper surface of the partition wall W may be at a level higher than a level of the upper surface of the adhesive regions DMR. The partition wall W may be formed as a portion of the adhesive layer 10b and may include the same material as the adhesive layer 10b.

In the example implementations, the width d of the non-adhesive region NMR may be defined as a maximum width in the horizontal direction D1 or D2 of the partition wall W.

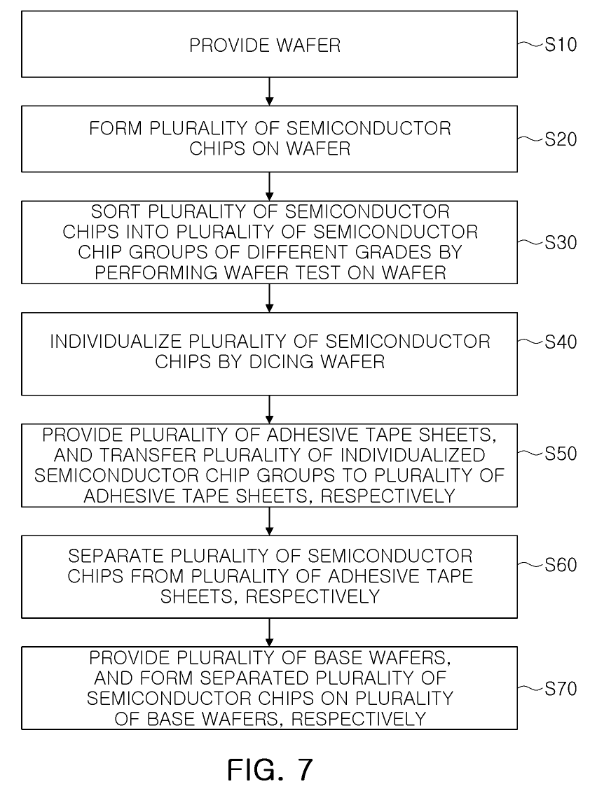

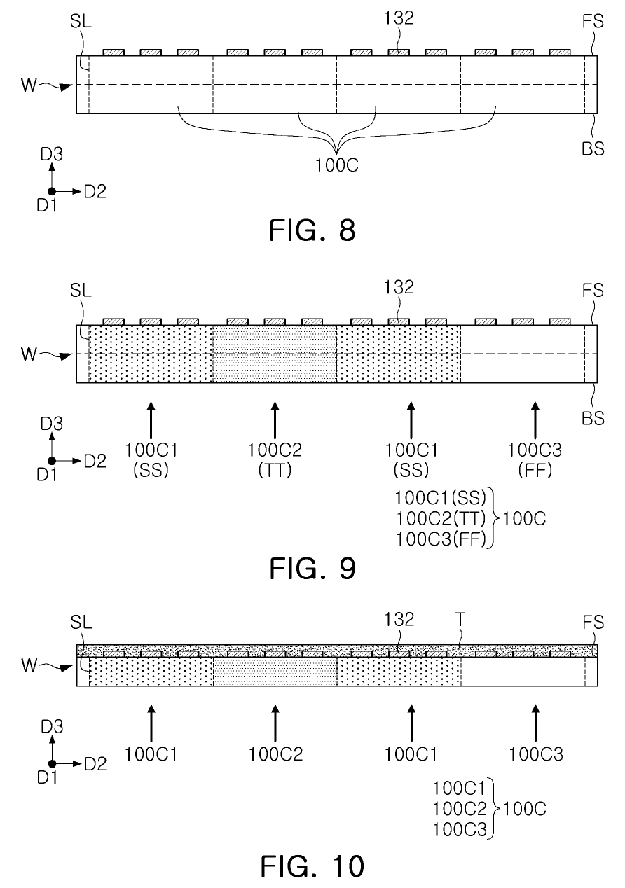

FIG. 5A is a plan diagram illustrating an adhesive tape sheet 1c according to some example implementations, illustrating an adhesive layer 10c of the adhesive tape sheet 1c. FIG. 5B is a cross-sectional diagram taken along line I-I’ in FIG. 5A.

Referring to FIGS. 5A and 5B, the example implementations may be the same as or similar to the example described with reference to FIGS. 1-4B, other than the configuration in which the adhesive regions DMR may be distinct by a groove G.

In the example implementations, the non-adhesive region NMR may be defined by the groove G. The groove G may be a structure recessed in a vertical direction downwardly from the upper surface of the first portion 10p1 of the adhesive layer 10b. A bottom surface of the groove G may be at a level lower than a level of the upper surface of the adhesive regions DMR.

In the example implementations, the width d of the non-adhesive region NMR may be defined as a maximum width in the horizontal direction D1 or D2 of the groove G.

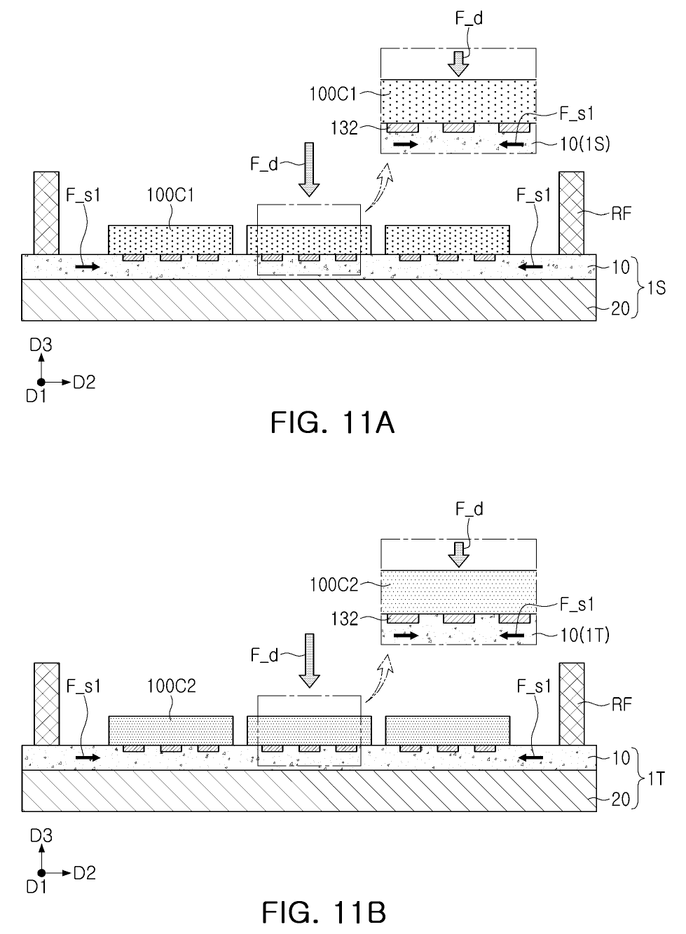

FIG. 6 is a plan diagram illustrating an adhesive tape sheet 1d according to some example implementations, illustrating an adhesive layer 10d of the adhesive tape sheet 1d.

Referring to FIG. 6, the adhesive tape sheet 1d may be the same as or similar to the example described with reference to FIGS. 1-5B, other than the configuration in which an adhesive layer 10d further including a third portion 10p3 surrounding the second portion 10p2 and distinct from the second portion 10p2.

The third portion 10p3 may be a region surrounding the second portion 10p2 at an edge of the adhesive layer 10d. The third portion 10p3 may include substantially the same material as the first portion 10p3. In another aspect, the third portion 10p3 may be defined as a region in which the adhesive forming the second portion 10p2 is not applied.

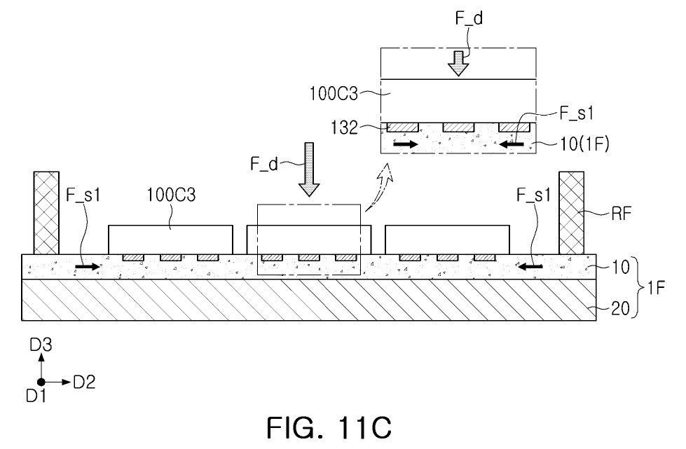

FIG. 7 is a flowchart illustrating processes of a method of manufacturing a semiconductor device using adhesive tape sheets 1, 1a, 1b, 1c, and 1d in order according to some example implementations.

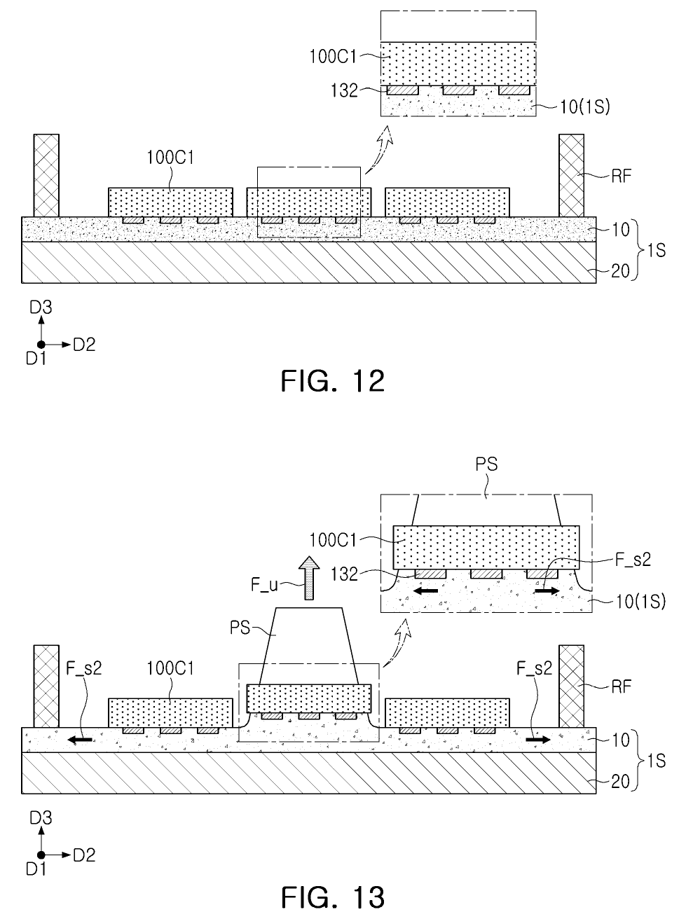

FIGS. 8, 9, 10, 11A, 11B, 11C, 12, 13, 14A, 14B, and 14C are vertical cross-sectional diagrams illustrating a method of manufacturing a semiconductor device using adhesive tape sheets 1, 1a, 1b, 1c, and 1d according to some example implementations.

Referring to FIGS. 7 and 8, a wafer W may be provided (S10), and a plurality of semiconductor chips 100C may be formed on the wafer W (S20).

The wafer W may be provided (S10). The wafer W may include a semiconductor wafer. The wafer W may include, for example, a semiconductor element such as silicon, germanium, or a compound semiconductor such as silicon carbide (SiC), gallium arsenide (GaAs), indium arsenide (InAs), and indium phosphide (InP). The wafer W may be defined to include a front surface FS on which connection pads 132 are formed and a back surface BS of which at least a portion is removed by a back grinding process.

A plurality of semiconductor chips 100C may be formed on the wafer W (S20). Each of the plurality of semiconductor chips 100C may include a substrate, a circuit layer, and a plurality of connection pads 132. The substrate may include the semiconductor element or the compound semiconductor. The circuit layer may be disposed adjacent to one surface of the substrate, for example, the front surface FS of the wafer W.

The plurality of connection pads 132 may be formed on the front surface FS of the wafer W. In some example implementations, the plurality of connection pads 132 may be referred to as a front pad. The plurality of connection pads 132 may include at least one of copper (Cu), nickel (Ni), gold (Au), silver (Ag), titanium (Ti), titanium nitride (TiN), tantalum (Ta), or tantalum nitride (TaN). For example, the connection pads 132 may include at least one of copper (Cu) or an alloy thereof.

A scribe line SL may be formed between the plurality of semiconductor chips 100C. The scribe line SL may be a region defining a space between the plurality of semiconductor chips 100C adjacent to each other, and may be used as a cutting path for separating the individual semiconductor chips 100C from the wafer W through a subsequent dicing process. The scribe line SL may generally not perform an electrical function, and may be a portion in which a circuit pattern is not typically formed. In some example implementations, an alignment mark, a test pattern, or an identification mark for equipment recognition may be formed on the scribe line SL.

Referring to FIGS. 7 and 9, by performing a wafer test on the wafer W, the plurality of semiconductor chips 100C may be sorted into a plurality of semiconductor chip groups of different grades (S30).

A wafer test may be performed on the wafer W.

The wafer test may include an electrical die sorting (EDS) test.

The wafer test may include sorting the plurality of semiconductor chips 100C into semiconductor chip groups of different grades based on at least one of parameters such as an operation speed, current consumption, or threshold voltage range.

For example, the semiconductor chip groups may include first to third semiconductor chip groups SS, TT, and FF. The first semiconductor chip group SS may include at least one first semiconductor chip 100C1 sorted into a first grade. The second semiconductor chip group TT may include at least one second semiconductor chip 100C2 sorted into a second grade. The third semiconductor chip group FF may include at least one third semiconductor chip 100C3 sorted into a third grade. Each of the at least one of the first to third semiconductor chips 100C1, 100C2, and 100C3 may include a plurality of semiconductor chips.

In example implementations, the first grade may be a higher grade than the second grade, and the second grade may be a higher grade than the third grade. In example implementations, the higher the grade, the better the quality or performance level of the semiconductor chip may be. For example, the first semiconductor chip 100C1 of the first grade may have relatively improved electrical properties or reliability properties than those of the second semiconductor chip 100C2 of the second grade. The second semiconductor chip 100C2 of the second grade may have relatively improved electrical properties or reliability properties than those of the third semiconductor chip 100C3 of the third grade.

Referring to FIGS. 7 and 10, the plurality of semiconductor chips 100C may be individualized by dicing the wafer W (S40).

A tape T may be formed on the front surface FS of the wafer W, and by performing a back grinding process, a portion of the back surface BS of the wafer W may be removed. Thereafter, by dicing the wafer W, the plurality of semiconductor chips 100C may be individualized.

Referring to FIGS. 7, 11A, 11B, and 11C, a plurality of adhesive tape sheets 1S, 1T, and 1F may be provided, and the plurality of individualized semiconductor chip groups may be transferred to the plurality of adhesive tape sheets 1S, 1T, and 1F, respectively (S50).

The plurality of adhesive tape sheets 1S, 1T, and 1F may include, for example, a first adhesive tape sheet 1S, a second adhesive tape sheet 1T, and a third adhesive tape sheet 1F. Each of the first to third adhesive tape sheets 1S, 1T, and 1F may include one of the adhesive tape sheets 1, 1a, 1b, 1c, and 1d described with reference to FIGS. 1-6 .

The first semiconductor chips 100C1 of the first semiconductor chip group (‘SS’ in FIG. 9 ), the second semiconductor chips 100C2 of the second semiconductor chip group (‘TT’ in FIG. 9 ), and the third semiconductor chips 100C3 of the third semiconductor chip group (‘FF’ in FIG. 9 ), sorted into different grades, may be transferred onto different adhesive tape sheets, respectively. For example, the first semiconductor chips 100C1 may be transferred onto the first adhesive tape sheet 1S (see FIG. 11A), the second semiconductor chips 100C2 may be transferred onto the second adhesive tape sheet 1T (see FIG. 11B), and the third semiconductor chips 100C3 may be transferred onto the third adhesive tape sheet 1F (see FIG. 11C).

A support structure RF may be formed at edges of the first to third adhesive tape sheets 1S, 1T, and 1F. The support structure RF may include a ring frame stably supporting the first to third semiconductor chips 100C1, 100C2, and 100C3. Referring to FIG. 2, the support structure RF may be formed on the second portion 10p2.

The transferring of the first to third semiconductor chips 100C1, 100C2, and 100C3 onto the corresponding first to third adhesive tape sheets 1S, 1T, and 1F may be performed under first pressing force F_d. The first pressing force F_d may be applied in a downward direction perpendicular to the upper surface of each of the first to third adhesive tape sheets 1S, 1T, and 1F.

Also, the first shear force F_s1 may be applied in a direction toward the point at which the first pressing force F_d is applied. At least a portion of the first shear force F_s1 may be applied substantially parallel to the upper surface of the first to third adhesive tape sheets 1S, 1T, and 1F. It may be interpreted that the first shear force F_s1 may be due to physical properties in which viscosity changes depending on an external force or deformation condition as the first to third adhesive tape sheets 1S, 1T, and 1F include a polymer composition including a thixotropic agent.

The viscosity of each adhesive layer 10 of the first to third adhesive tape sheets 1S, 1T, and 1F may be reduced by the first pressing force F_d and the first shear force F_s1. Accordingly, the adhesive layer 10 may fill a space between the connection pads 132 without voids. Accordingly, mounting stability of each of the first to third semiconductor chips 100C1, 100C2, and 100C3 may be improved.

Referring to FIGS. 7 and 12, after performing the transfer process in FIGS. 11A-11C, the preliminary semiconductor structure may be maintained for a predetermined period of time without an external force or separate action. In the example implementations, for ease of description, the first semiconductor chip 100C1 transferred onto the first adhesive tape sheet 1S may be mainly described.

The preliminary semiconductor structure may refer to the first to third semiconductor chip (‘100C1’ in FIG. 11A, ‘100C2’ in FIG. 11B, and ‘100C3’ in FIG. 11C) transferred onto the first to third adhesive tape sheets (‘1S’ in FIG. 11A, ‘1T’ in FIG. 11B, and ‘1F’ in FIG. 11C) described with reference to FIGS. 11A to 11C.

In this case, viscosity of the adhesive layer 10 of each of the first to third adhesive tape sheets 1S, 1T, and 1F may increase again over time.

Referring to FIGS. 7 and 13, the plurality of semiconductor chips (e.g., 100C1, 100C2, and 100C3) may be separated from the plurality of adhesive tape sheets 1S, 1T, and 1F (S60), respectively. In the example implementations, for ease of description, the first semiconductor chip 100C1 transferred onto the first adhesive tape sheet 1S may be described as a center.

The separation of the first semiconductor chip 100C1 from the first adhesive tape sheet 1S may be performed under a first pulling force. The first semiconductor chip 100C1 may be picked up using a pick-up device PS. The first pulling force may be applied in an upward direction D3 perpendicular to the upper surface of the first adhesive tape sheet 1S.

Also, the second shear force F_s2 may be applied in a direction away from the point at which the first pulling force is applied. At least a portion of the second shear force F_s2 may be applied substantially parallel to the upper surface of the first adhesive tape sheet 1S. It may be interpreted that the second shear force F_s2 may be due to physical properties in which viscosity changes depending on an external force or deformation condition as the first adhesive tape sheet 1S includes a polymer composition including a thixotropic agent.

The viscosity of the adhesive layer 10 of the first adhesive tape sheet 1S may be reduced by the first pressing force F_d and the second shear force F_s2. Accordingly, at least a portion of the adhesive layer 10 may be elongated, e.g., stretched, in the upward direction D3.

The adhesive layer 10 may be completely removed from the first semiconductor chip 100C1, and no residue may be left between the connection pads 132.

Referring to FIGS. 7, 14A, 14B, and 14C, a plurality of base wafers 200W1, 200W2, and 200W3 may be provided, and each of the separated plurality of semiconductor chips (e.g., 100C1, 100C2, and 100C3) may be formed on the plurality of base wafers 200W1, 200W2, and 200W3, respectively (S70).

The plurality of base wafers 200W1, 200W2, and 200W3 may be provided. The plurality of base wafers 200W1, 200W2, and 200W3 may include, for example, first to third base wafers 200W1, 200W2, and 200W3. Each of the first to third base wafers 200W1, 200W2, and 200W3 may include a plurality of preliminary base chips distinguished from each other by a scribe line SL.

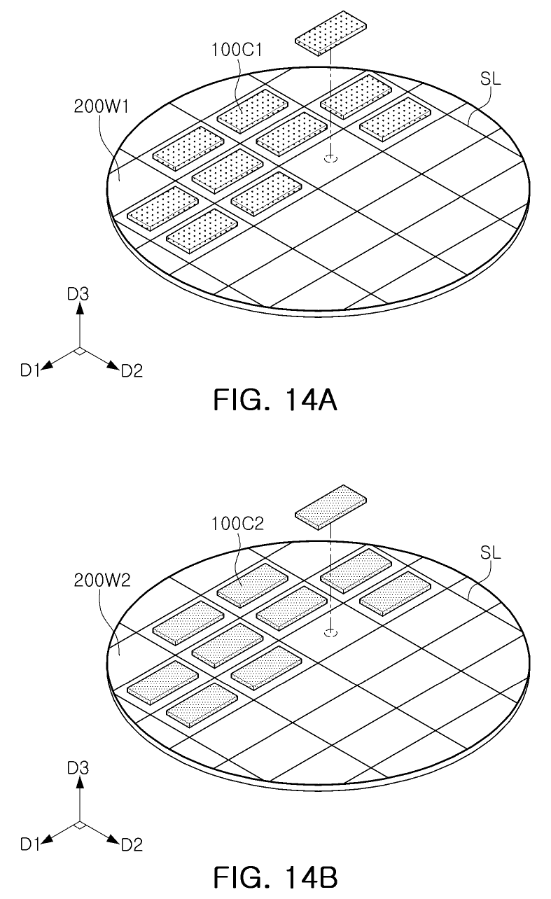

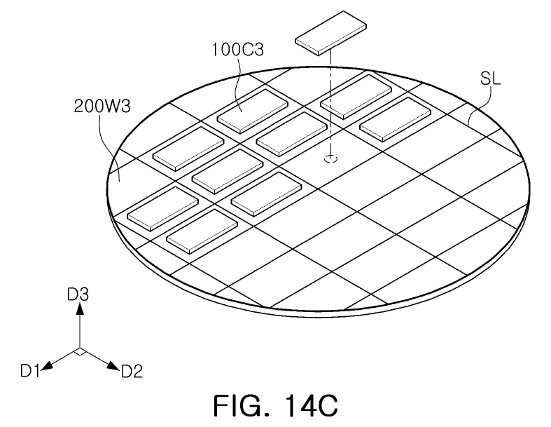

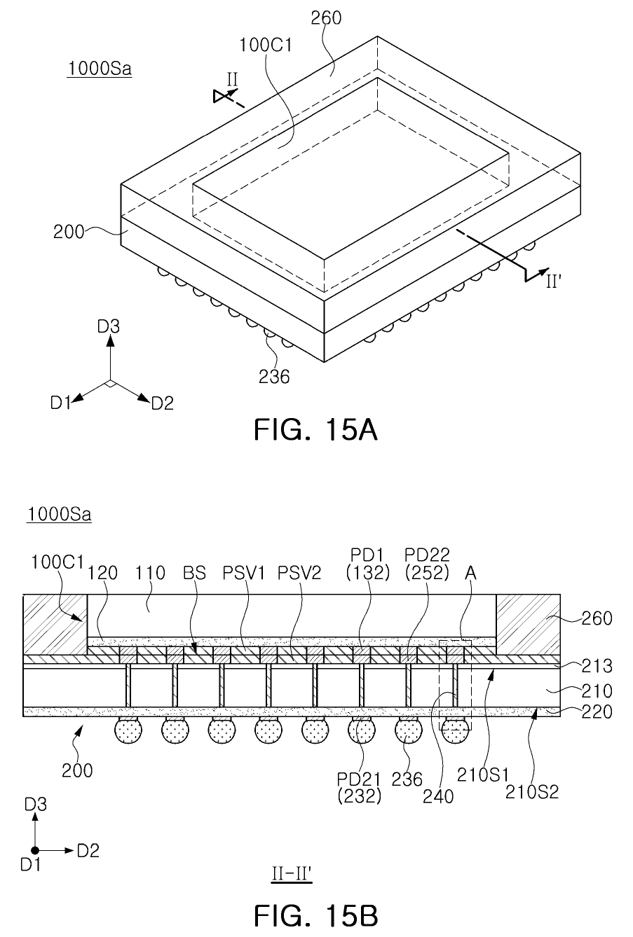

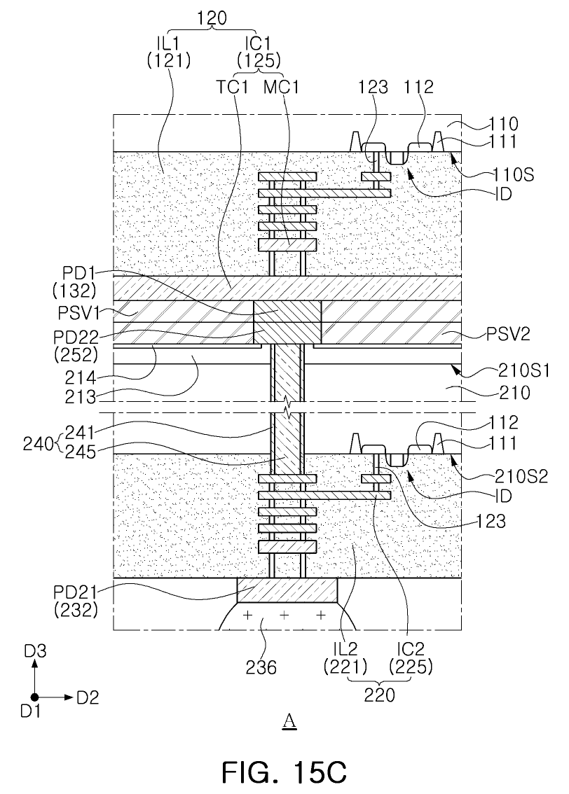

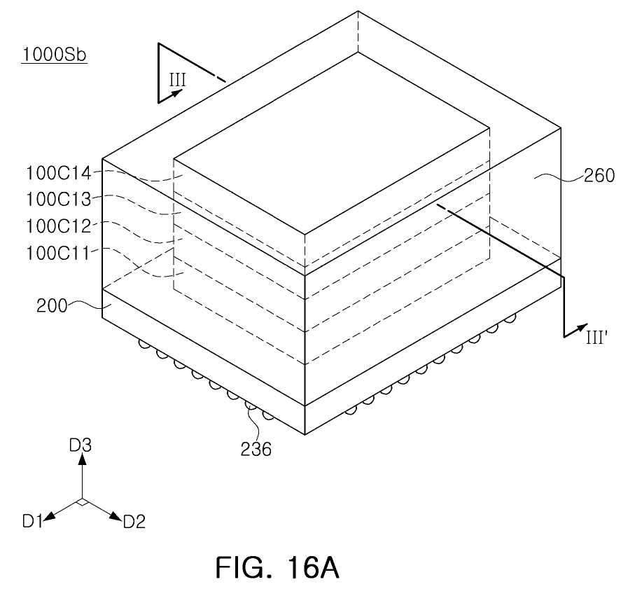

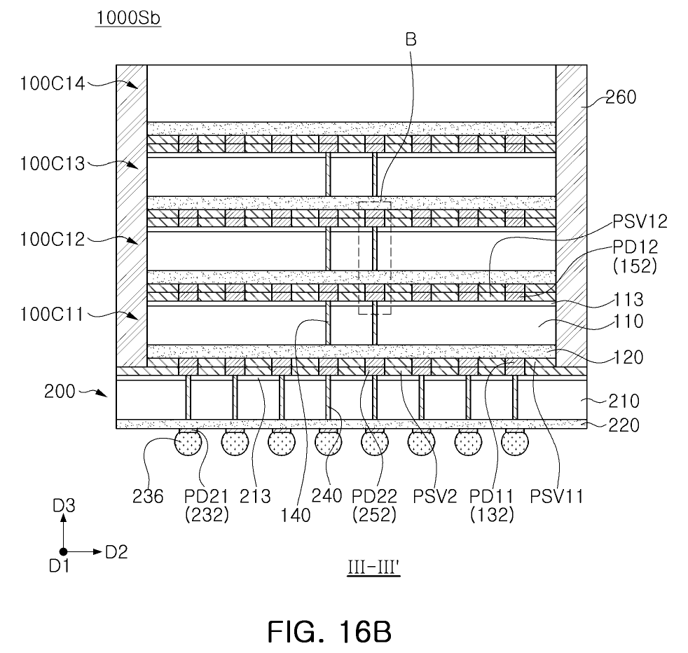

A lower passivation layer (e.g., ‘PSV1’ in FIG. 15C or ‘PSV11’ in FIG. 16C) surrounding the connection pad 132 may be formed on each of the separated first to third semiconductor chips 100C1, 100C2, and 100C3 described with reference to FIG. 13. Thereafter, the first to third semiconductor chips 100C1, 100C2, and 100C3 may be formed on the first to third base wafers 200W1, 200W2, and 200W3, respectively. For example, the first semiconductor chip 100C1 may be formed on the first base wafer 200W1 (see FIG. 14A), the second semiconductor chip 100C2 may be formed on the second base wafer 200W2 (see FIG. 14B), and the third semiconductor chip 100C3 may be formed on the third base wafer 200W3 (see FIG. 14C).

Each of the first to third base wafers 200W1, 200W2, and 200W3 may include preliminary base chips sorted to a grade substantially the same as the grade assigned to the corresponding first to third semiconductor chips 100C1, 100C2, and 100C3. The first base wafer 200W1 may include, for example, first preliminary base chips sorted into a first grade (see FIG. 14A), the second base wafer 200W2 may include second preliminary base chips sorted into a second grade (see FIG. 14B), and the third base wafer 200W3 may include third preliminary base chips sorted into a third grade (see FIG. 14C).

Thereafter, in some example implementations, the first base wafer 200W1 may be diced along the scribe line SL, and a mold layer (‘260’ in FIG. 15A) and connection bumps (‘236’ in FIG. 15A) may be formed, thereby forming a semiconductor device (‘1000Sa’ in FIG. 15A). The semiconductor device 1000S may be described in greater detail with reference to FIGS. 15A and 15B.

Thereafter, in some example implementations, a plurality of first semiconductor chips 100C1 may be formed on the first semiconductor chip 100C1, and the first base wafer 200W1 may be diced along the scribe line SL, and a mold layer (‘260’ in FIG. 16A) and connection bumps (‘236’ in FIG. 16A) may be formed. Accordingly, a semiconductor device 1000Sb including a first base chip (‘200’ in FIG. 16A) and a plurality of first semiconductor chips 100C1 stacked on the first base chip may be formed. The semiconductor device 1000Sb may be described in greater detail with reference to FIGS. 16A, 16B, and 16C. A semiconductor device including a second base chip and a plurality of second semiconductor chips 100C2 stacked on the second base chip, and a semiconductor device including a third base chip and a plurality of third semiconductor chips 100C3 stacked on the third base chip may also be formed in substantially the same manner as the semiconductor device 1000Sb.

FIG. 15A is a perspective diagram illustrating a semiconductor device 1000Sa according to some example implementations. FIG. 15B is a cross-sectional diagram taken along line II-II’ in FIG. 15A. FIG. 15C is an enlarged diagram illustrating region “B” in FIG. 15B.

Referring to FIGS. 15A, 15B, and 15C, the semiconductor device 1000Sa may include two or more semiconductor chips, for example, a first semiconductor chip 100C1 and a base chip 200, opposing each other in a vertical direction D3. In some example implementations, the semiconductor device 1000Sa may be referred to as a semiconductor chip stack structure.

In the example implementations, the first semiconductor chip 100C1 may include the first semiconductor chip 100C1 described with reference to FIGS. 8, 9, 10, 11A, 11B, 11C, 12, 13, 14A, 14B, and 14C.

In the example implementations, the base chip 200 may include a plurality of base chips of the first base wafer 200W1 described with reference to FIGS. 14A, 14B, and 14C.

Two or more first semiconductor chips 100C1 may be disposed on the base chip 200. The first semiconductor chip 100C1 and the base chip 200 may include chiplets forming a multi-chip module (MCM). In example implementations, the semiconductor device 1000Sa may further include a mold layer 260 encapsulating at least a portion of each of the first semiconductor chip 100C1 and the base chip 200. The mold layer 260 may include, for example, an epoxy mold compound (EMC), but the material of the mold layer 260 is not limited to any particular example.

The first semiconductor chip 100C1 and the base chip 200 may be bonded and coupled to each other by metal-to-metal bonding and dielectric-to-dielectric bonding. The semiconductor device 1000Sa may have a bonding surface BS in which a first lower pad PD1 and a first passivation layer PSV1 of a first semiconductor chip 100C1 and a second upper pad PD22 and a second passivation layer PSV2 of a base chip 200 are bonded and coupled to each other.

The first semiconductor chip 100C1 may include a first substrate 110, a first circuit layer 120, a first passivation layer PSV1, and a plurality of first lower pads PD1.

The first substrate 110 may be a semiconductor substrate. The first substrate 110 may include, for example, a semiconductor element such as silicon, germanium, or a compound semiconductor such as silicon carbide (SiC), gallium arsenide (GaAs), indium arsenide (InAs), and indium phosphide (InP). The first substrate 110 may include a conductive region 112 and an isolation region 113 formed on one surface 110S. The conductive region 112 may be, for example, a well doped with impurities or a structure doped with impurities. The isolation region 113 may be a device isolation structure having a shallow trench isolation (STI) structure, and may include silicon oxide.

The first circuit layer 120 may be disposed on one surface 110S of the first substrate 110 on which the conductive region 112 is formed. The first circuit layer 120 may include individual devices ID, a first insulating layer IL1, and a first interconnection IC1. Hereinafter, the first insulating layer IL1 may be referred to as a front insulating layer or an interlayer insulating layer 121. The first interconnection IC1 may be referred to as an interconnection structure 125.

The individual devices ID may be disposed on one surface 110S of the first substrate 110. The individual devices ID may be electrically connected to the conductive region 112. The individual devices ID may include various active devices and/or passive devices, for example, FET such as planar FET or FinFET, memory devices such as flash memory, DRAM, SRAM, EEPROM, PRAM, MRAM, FeRAM, RRAM, logic devices such as AND, OR, NOT, system LSI, CIS, MEMS, or the like.

The interlayer insulating layer 121 may be formed to cover the individual devices ID and interconnection structure 125, and may electrically isolate the individual devices ID disposed on the first substrate 110. The interlayer insulating layer 121 may include flowable oxide (FOX), tonen silazen (TOSZ), undoped silica glass (USG), borosilica glass (BSG), phosphosilica glass (PSG), borophosphosilica glass (BPSG), plasma enhanced tetra ethyl ortho silicate (PETEOS), fluoride silicate glass (FSG), high density plasma oxide (HDP), plasma enhanced oxide (PEOX), flowable chemical vapor deposition (FCVD) oxide, or a combination thereof. At least a partial region of the interlayer insulating layer 121 surrounding the interconnection structure 125 may be configured as a low-κ dielectric layer. The interlayer insulating layer 121 may be formed using a chemical vapor deposition (CVD), a flowable-CVD process, or a spin coating process.

The interconnection structure 125 may be formed as a multilayer structure including a plurality of interconnection patterns and a plurality of vias, for example, formed of aluminum (Al), gold (Au), cobalt (Co), copper (Cu), nickel (Ni), lead (Pb), tantalum (Ta), tellurium (Te), titanium (Ti), tungsten (W), or a combination thereof. A barrier film (not illustrated) including titanium (Ti), titanium nitride (TiN), tantalum (Ta), or tantalum nitride (TaN) may be disposed between the interconnection pattern or/and the via and the interlayer insulating layer 121. The interconnection structure 125 may be electrically connected to the individual devices ID by the interconnection portions 123 (e.g., contact plugs). The interconnection structure 125 may include a signal interconnection, power interconnection, and ground interconnection.

The first interconnection IC1 may include first intermediate conductors MC1 and first uppermost conductors TC1. Hereinafter, the first uppermost conductors TC1 may be referred to as “connection conductors.” The first intermediate conductors MC1 may be disposed in the first insulating layer IL1. The first intermediate conductors MC1 may be positioned between one surface 110S of the first substrate 110 and the first uppermost conductors TC1. The first uppermost conductors TC1 may be positioned between the first intermediate conductors MC1 and a plurality of first lower pads PD1 in the vertical direction D3. The first uppermost conductors TC1 may include aluminum (Al) or an alloy thereof, but some example implementations thereof is not limited thereto. In example implementations, the first uppermost conductors TC1 may include a material similar to the first intermediate conductors MC1, for example, copper (Cu) or an alloy thereof.

The plurality of first lower pads PD1 may be disposed on the first interconnection IC1. The plurality of first lower pads PD1 may be electrically connected to the first interconnection IC1 through the first uppermost conductor TC1. The plurality of first lower pads PD1 may include at least one of copper (Cu), nickel (Ni), gold (Au), silver (Ag), titanium (Ti), titanium nitride (TiN), tantalum (Ta), or tantalum nitride (TaN). For example, the plurality of first lower pads PD1 may include at least one of copper (Cu) or an alloy thereof. The plurality of first lower pads PD1 may correspond to the connection pads 132 described with reference to FIGS. 8, 9, 10, 11A, 11B, 11C, 12, 13, 14A, 14B, and 14C. In some example implementations, the connection pads 132 may be referred to as front pads for ease of description. The first lower pads PD1 of at least a portion of the plurality of first lower pads PD1 may be in direct contact with the second upper pads PD22 of the second semiconductor chip 200.

The plurality of second upper pads PD22 may be disposed on the through-electrodes 240. The plurality of second upper pads PD22 may be electrically connected to the second interconnection IC2 through the through-electrodes 240. The plurality of second upper pads PD1 may include at least one of copper (Cu), nickel (Ni), gold (Au), silver (Ag), titanium (Ti), titanium nitride (TiN), tantalum (Ta), or tantalum nitride (TaN). For example, the plurality of second upper pads PD22 may include at least one of copper (Cu) or an alloy thereof. To distinguish the positions of elements in the base chip 200, the plurality of second upper pads PD22 may be referred to as back surface pads 252. The back surface pads 252 may be electrically connected to the second interconnection IC2 and/or the second upper surface pads 232 through through-electrodes 240.

The first passivation layer PSV1 may be formed to surround a side surface of a plurality of first lower pads PD1. The first passivation layer PSV1 may form a bonding surface BS providing dielectric bonding between the plurality of first lower pads PD1. The first passivation layer PSV1 may include, for example, silicon oxide (SiO) and/or silicon carbon nitride (SiCN). The first passivation layer PSV1 may be in direct contact with the second passivation layer PSV2 of the basechip 200.

The second passivation layer PSV2 may be formed to surround a side surface of the second upper pads PD22. The second passivation layer PSV2 may form a bonding surface BS providing for dielectric bonding between the plurality of second upper pads PD22. The second passivation layer PSV2 may include, for example, silicon oxide (SiO) and/or silicon carbon nitride (SiCN).

The base chip 200 may be disposed on one surface of the first semiconductor chip 100C1. The base chip 200 may be disposed in a direction in which the plurality of second upper pads PD22 oppose the front pads 132 of the first semiconductor chip 100C1.

The base chip 200 may include a second substrate 210, a second circuit layer 220, a second passivation layer PSV2, a plurality of second upper pads PD12, through-vias 240 and a plurality of second lower pads PD21. The base chip 200 may include elements substantially similar to the elements of the first semiconductor chip 100C1, for example, the second substrate 210, the second circuit layer 220, the second passivation layer PSV2, and the plurality of second lower pads PD21. Accordingly, the same as or similar to elements may be referred to by the same as or similar to terms and/or reference numerals, and overlapping descriptions will not be provided hereinafter. The second insulating layer IL2 may be referred to as a front insulating layer or an interlayer insulating layer 221, and the second interconnection IC2 may be referred to as an interconnection structure 225.

Through-electrodes 240 may penetrate one surface 210S1 and the other surface 210S2 of the second substrate 210 and may electrically connect the second interconnection IC2 to the plurality of second upper pads PD22. One surface 210S1 of the second substrate 210 may be referred to as a front surface or a back surface depending on whether the active region 112 is formed. The through-electrodes 240 may include a via plug 245 and a side barrier layer 241 surrounding a side surface thereof. The via plug 245 may include, for example, tungsten (W), titanium (Ti), aluminum (Al), or copper (Cu), and may be formed by a plating process, a PVD process, or a CVD process. The side barrier layer 241 may include, for example, titanium (Ti), titanium nitride (TiN), tantalum (Ta), or tantalum nitride (TaN), and may be formed by a plating process, a PVD process, or a CVD process. A side insulating film (not illustrated) including an insulating material (e.g., high aspect ratio process (HARP) oxide) such as silicon oxide, silicon nitride, or silicon oxynitride may be formed between the side barrier layer 241 and the second substrate 210.

The through-electrodes 240 may penetrate an insulating protective layer 213 formed on one surface 210S1 of the second substrate 210. The insulating protective layer 213 may include, for example, silicon oxide (SiO), silicon nitride (SiN), silicon carbide (SiC), silicon oxynitride (SiON), or silicon carbonitride (SiCN). A buffer film 214, such as a polishing stop layer or a barrier, may be disposed on the insulating protective layer 213. For example, the buffer film may include silicon nitride, silicon carbide, silicon oxynitride, or silicon carbonitride.

The plurality of second lower pads PD21 may be disposed on the other surface 210S2 of the second substrate 210. The plurality of second lower pads PD21 may be referred to as front pads 232. The plurality of second lower pads PD21 may be connected to connection bumps 236. The connection bumps 236 may include, for example, tin (Sn), indium (In), bismuth (Bi), antimony (Sb), copper (Cu), silver (Ag), zinc (Zn), lead (Pb), and/or alloys thereof.

FIG. 16A is a perspective diagram illustrating a semiconductor device 1000Sb according to some example implementations. FIG. 16B is a cross-sectional diagram taken along line III-III’ in FIG. 16A. FIG. 16C is an enlarged diagram illustrating region “B” in FIG. 16B.

Referring to FIGS. 16A, 16B, and 16C, the semiconductor device 1000Sb may be configured the same as or similar to the example described with reference to FIGS. 15A-15C, other than the configuration in which a plurality of first semiconductor chips 100C11, 100C12, 100C13, and 100C14 are stacked on a base chip 200 in a vertical direction D3. In some example implementations, the semiconductor device 1000Sb may be referred to as a semiconductor chip stack structure.

In the example implementations, each of the plurality of first semiconductor chips 100C11, 100C12, 100C13, and 100C14 may include the first semiconductor chip 100C1 described with reference to FIGS. 8, 9, 10, 11A, 11B, 11C, 12, 13, 14A, 14B, and 14C.

In the example implementations, the base chip 200 may include a plurality of base chips of the first base wafer 200W1 described with reference to FIGS. 14A, 14B, and 14C.

The plurality of first semiconductor chips 100C11, 100C12, 100C13, and 100C14 may include the uppermost first semiconductor chip 100C14, and the first semiconductor chips 100C11, 100C12, and 100C13 between the uppermost first semiconductor chip 100C14 and the base chip 200. The plurality of first semiconductor chips 100C11, 100C12, 100C13, and 100C14 may include elements the same as or similar to those of the first semiconductor chip 100C1 described with reference to FIGS. 15A-15C. However, some of the first semiconductor chips 100C11, 100C12, and 100C13, other than the uppermost first semiconductor chip 100C14, may further include a first through-electrode 140, a first upper pads PD12, and a first upper passivation layer PSV12. An upper surface of the uppermost first semiconductor chip 100C14 may not be covered by the mold layer 260, or in example implementations, the upper surface may be covered by the mold layer 260. The number of semiconductor chips stacked on the base chip 200 may not be limited. For example, the number of the semiconductor chips may include eight, 12, or 20.

The first through-electrodes 140 may penetrate one surface 110S1 and the other surface 110S2 of the first substrate 110 and may electrically connect the first interconnection IC1 to the first upper pads PD12. The first through-electrodes 140 may include a via plug 145 and a side barrier layer 141 surrounding a side surface thereof. The via plug 145 may include, for example, tungsten (W), titanium (Ti), aluminum (Al), or copper (Cu), and may be formed by a plating process, a PVD process, or a CVD process. The side barrier layer 141 may include, for example, titanium (Ti), titanium nitride (TiN), tantalum (Ta), or tantalum nitride (TaN), and may be formed by a plating process, a PVD process, or a CVD process. A side insulating film (not illustrated) including an insulating material (e.g., HARP oxide), such as silicon oxide, silicon nitride, or silicon oxynitride, may be formed between the side barrier layer 141 and the first substrate 110.

The first upper pads PD12 may be disposed on the first through-electrodes 140. The first upper pads PD12 may be electrically connected to the first interconnection IC1 through the first through-electrodes 140. The first upper pads PD12 may include at least one of copper (Cu), nickel (Ni), gold (Au), silver (Ag), titanium (Ti), titanium nitride (TiN), tantalum (Ta), or tantalum nitride (TaN). For example, the first upper pads PD12 may include at least one of copper (Cu) or an alloy thereof. To distinguish positions of elements in the first semiconductor chip 100, the first upper pads PD12 may be referred to as back surface pads 152. The first upper pads PD12 may be in contact with the first lower pads PD11 adjacent to each other in the vertical direction D3.

The first upper passivation layer PSV12 may be formed to surround a side surface of the second upper pads PD12. The first upper passivation layer PSV12 may form a bonding surface provided for dielectric bonding between the second upper pads PD12. The first upper passivation layer PSV12 may include, for example, silicon oxide (SiO) and/or silicon carbon nitride (SiCN). The first upper passivation layer PSV12 may be in contact with the first lower passivation layer PSV11 adjacent in the vertical direction D3.

In example implementations, the base chip 200 may be a buffer chip or a control chip including a plurality of logic devices and/or memory devices. The base chip 200 may transfer a signal from the first semiconductor chips 100C11, 100C12, 100C13, and 100C14 stacked thereon to an external entity, and may also transfer a signal and power from an external entity to the first semiconductor chips 100C11, 100C12, 100C13, and 100C14. The first semiconductor chips 100C11, 100C12, 100C13, and 100C14 may be memory chips including volatile memory devices such as DRAM and SRAM, or nonvolatile memory devices such as PRAM, MRAM, FeRAM, or RRAM.

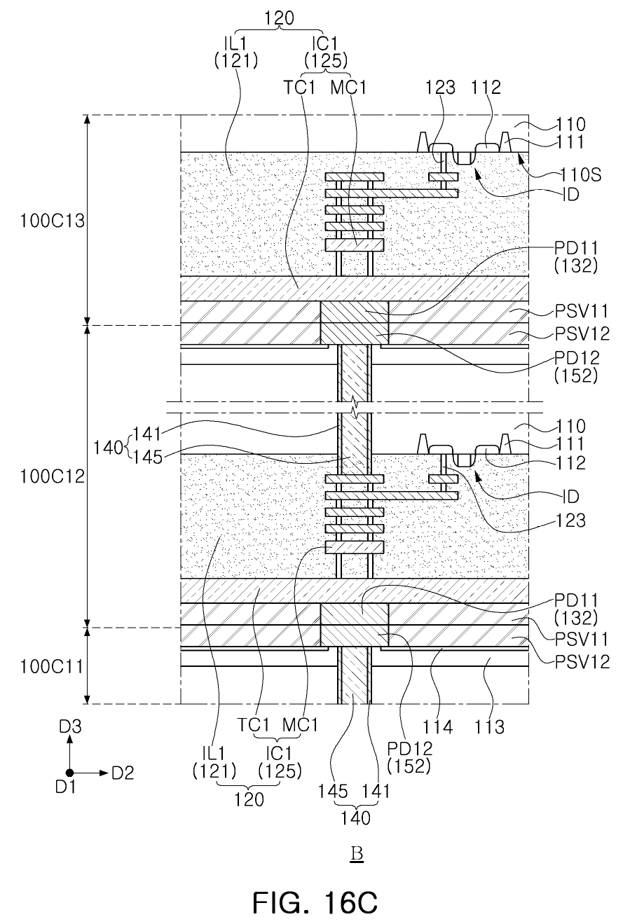

FIG. 17 is a perspective diagram illustrating a semiconductor device 1000Sc according to some example implementations.

Referring to FIG. 17, the semiconductor device 1000Sc may be configured the same as or similar to the example described with reference to FIGS. 15A, 15B, 15C, 16A, 16B, and 16C, other than the configuration in which a plurality of first semiconductor chips 100C11, 100C12, and 10013 disposed on the base chip 200 in the horizontal direction D1 and D2 are included. In some example implementations, the semiconductor device 1000Sc may be referred to as a semiconductor chip stack structure.

In the example implementations, each of the plurality of first semiconductor chips 100C11, 100C12, and 10013 may include the first semiconductor chip 100C1 described with reference to FIGS. 8, 9, 10, 11A, 11B, 11C, 12, 13, 14A, 14B, and 14C.

In the example implementations, the base chip 200 may include a plurality of base chips of the first base wafer 200W1 described with reference to FIGS. 14A, 14B, and 14C.

The plurality of first semiconductor chips 100C11, 100C12, and 10013 and the base chip 200 may be chiplets included in a multi-chip module (MCM). The plurality of first semiconductor chips 100C11, 100C12, and 10013 may include a first chiplet 100C11, a second chiplet 100C12, and a third chiplet 100C13. For example, the first chiplet 100C11 may be configured as a central processor (CPU), the second chiplet 100C12 may be configured as a graphics processor (GPU), the third chiplet 100C13 may be configured as a field programmable gate array (FPGA) chip, and the base chip 200 may include an I/O chip or an active interposer. For example, the base chip 200 may include an I/O device, a DC/DC converter, a sensor, a test circuit, or the like.

The first chiplet 100C12, the second chiplet 100C12, and the third chiplet 100C13 may be bonded to each other on the base chip 200.

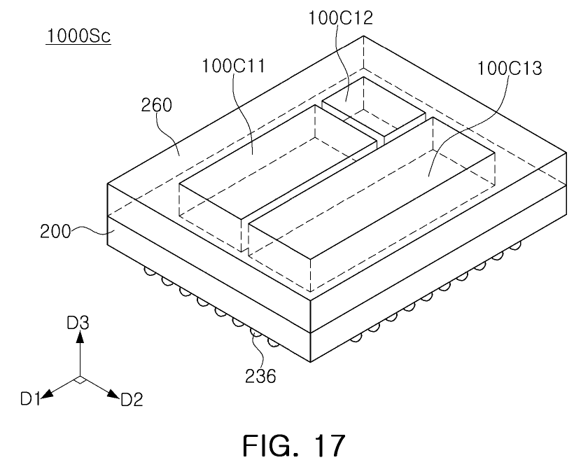

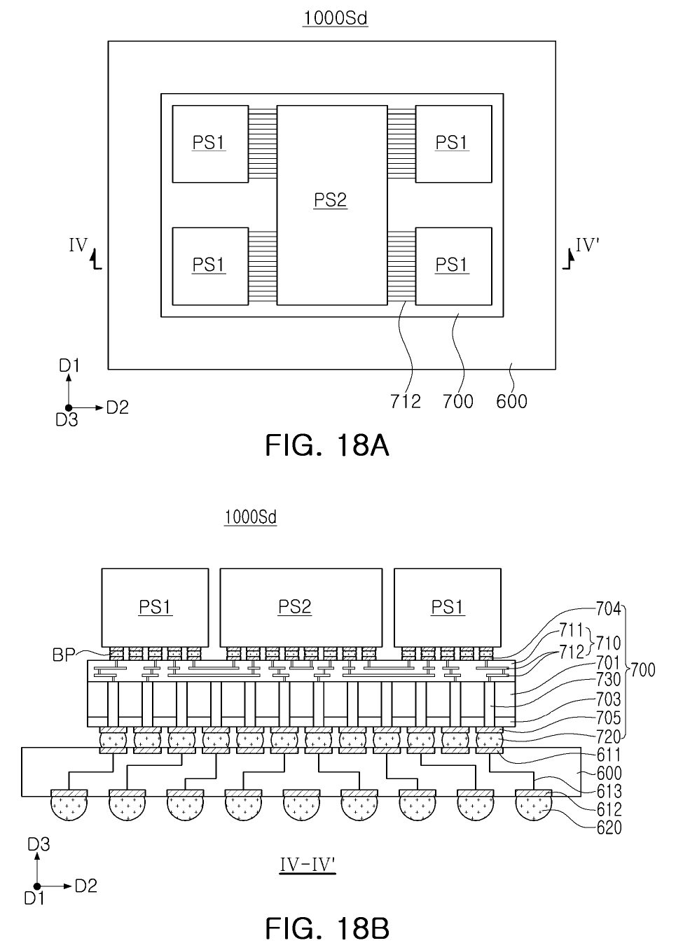

FIG. 18A is a perspective diagram illustrating a semiconductor device 1000Sd according to some example implementations. FIG. 18B is a cross-sectional diagram taken along line IV-IV’ in FIG. 18A.

Referring to FIGS. 18A and 18B, the semiconductor device 1000Sd may include a package substrate 600, an interposer substrate 700, and at least one package structure PS1 and PS2. The number of the at least one package structure PS1 and PS2 may be more or less than the example illustrated in the drawings. In some example implementations, the semiconductor device 1000Sd may be referred to as a semiconductor chip stack structure.

The at least one package structure PS1 and PS2 may include a first package structure PS1 and a second package structure PS2 interconnected through the interposer substrate 700.

The first package structure PS1 may be a high-performance memory device such as a high bandwidth memory (HBM), a hybrid memory cubic (HMC), or the like. For example, the first package structure PS1 may be understood as a semiconductor device configured the same as or similar to the example described with reference to FIGS. 16A, 16B, and 16C. The first package structure PS1 may be connected to the interposer substrate 700 through metal bumps BP.

The second package structure PS2 may be a bare chip or a packaged chip in which a logic circuit or a memory circuit is formed. In example implementations, the second package structure PS2 may be understood as a stack chip structure configured the same as or similar to the example described with reference to FIG. 17. The second package structure PS2 may be connected to the interposer substrate 700 through the metal bumps BP. The second package structure PS2 may include a different type of semiconductor chip than the first package structure PS1. For example, the first package structure PS1 may include a logic chip, and the second package structure PS2 may include a memory chip.

The package substrate 600 may be a support substrate on which the interposer substrate 700 is mounted, and may be a substrate for a semiconductor package including a printed circuit board (PCB), a ceramic substrate, a glass substrate, a tape interconnection substrate, or the like. The package substrate 600 may include a lower pad 612, an upper pad 611, and an interconnection circuit 613. An external connection bump 620 connected to the lower pad 612 may be disposed on a lower surface of the package substrate 600. The external connection bump 620 may include, for example, a solder ball.

The interposer substrate 700 may include a substrate 701, a lower protective layer 703, a lower terminal 705, an interconnection structure 710, a conductive bump 720, and a through-via 730. The first package structure PS1 and the second package structure PS2 may be electrically connected to each other through the interposer substrate 700.

The substrate 701 may be formed as, for example, one of a silicon substrate, an organic substrate, a plastic substrate, and a glass substrate. When the substrate 701 is a silicon substrate, the interposer substrate 700 may be referred to as a silicon interposer. Differently from the example illustrated in the drawings, when the substrate 701 is an organic substrate, the interposer substrate 700 may be referred to as a panel interposer.

The lower terminal 705 may be connected to a through-via 730. The lower terminal 705 may be electrically connected to the package substrate 600 through conductive bumps 720.

The interconnection structure 710 may be disposed on an upper surface of the substrate 701 and may include an interlayer insulating layer 711 and a single-layer or multilayer interconnection structure 712. When the interconnection structure 710 is configured as a multilayer interconnection structure, interconnection patterns on different layers may be connected to each other through contact vias. The upper terminal 704 connected to the interconnection structure 710 may be disposed on the interconnection structure 710.

The through-via 730 may extend from an upper surface of the substrate 701 to a lower surface and may penetrate the substrate 701. For example, the through-via 730 may extend into the interconnection structure 710 and may be electrically connected to interconnections of the interconnection structure 710. When the substrate 701 is silicon, the through-via 730 may be referred to as a TSV.

According to the aforementioned example implementations, an adhesive tape sheet which includes an adhesive layer including a polymer composition including a thixotropic agent and a method of manufacturing a semiconductor device using the same may be provided.

As used herein, the term “at least one of” can refer to and encompass any and all possible combinations of one or more of the associated listed terms. For example, the term “at least one of A, B, or C” means that (i) at least one of A, (ii) at least one of B, (iii) at least one of C, (iv) at least one of A and at least one of B, (v) at least one of B and at least one of C, (vi) at least one of A and at least one of C, or (vi) at least one of A, at least one of B and at least one of C are possible, where A, B and C may be singular or plural.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the example implementations have been illustrated and described above, it will be configured as apparent to those skilled in the art that modifications and variations could be made without departing from the scope of the present disclosure as defined by the appended claims.

What is claimed is:

1. A method of manufacturing a semiconductor device, the method comprising:
forming a plurality of semiconductor chips on a wafer;
sorting the plurality of semiconductor chips into a first semiconductor chip and a second semiconductor chip by performing a wafer test on the wafer;
providing a first adhesive tape sheet and a second adhesive tape sheet;
transferring the first semiconductor chip to the first adhesive tape sheet;
transferring the second semiconductor chip to the second adhesive tape sheet; and
providing a first base wafer and a second base wafer;
separating the first semiconductor chip from the first adhesive tape sheet and forming the first semiconductor chip on the first base wafer; and
separating the second semiconductor chip from the second adhesive tape sheet and forming the second semiconductor chip on the second base wafer,
wherein each of the first adhesive tape sheet and the second adhesive tape sheet includes an adhesive layer,
wherein the adhesive layer includes:
a first portion to which a corresponding semiconductor chip is attached; and
a second portion surrounding the first portion and to which a support structure is attached,
wherein the first portion includes a polymer composition including a thixotropic agent, and
wherein an adhesive force of the second portion is greater than an adhesive force of the second portion.

2. The method of claim 1, wherein the wafer test includes an electrical die sorting (EDS) test.

3. The method of claim 1, wherein the wafer test includes sorting the plurality of semiconductor chips into a plurality of grades based on at least one of an operation speed, a current consumption, or a threshold voltage range.

4. The method of claim 1, wherein a weight of the thixotropic agent relative to the polymer composition is in a range of 1 wt(%) to 5 wt(%).

5. The method of claim 1, wherein the thixotropic agent includes an oil-based thixotropic agent or an aqueous thixotropic agent.

6. The method of claim 5, wherein the oil-based thixotropic agent is one or more selected from a group consisting of fumed silica, polyamide wax, and hydrogenated castor oil.

7. The method of claim 5, wherein the aqueous thixotropic agent is one or more selected from a group consisting of synthetic silica and cellulose derivatives.

8. The method of claim 1,
wherein the each of the first adhesive tape sheet and the second adhesive tape sheet further includes a base layer on which the adhesive layer is positioned, and
wherein a thickness of the adhesive layer is in a range of 10 μm to 50 μm, and
wherein a thickness of the base layer is in a range of 50 μm to 100 μm.

9. The method of claim 1,
wherein the first semiconductor chip includes a lower passivation layer and lower pads,
wherein the first base wafer includes an upper passivation layer and upper pads,
wherein the lower pads are bonded to the upper pads, and
wherein the lower passivation layer is bonded to the upper passivation layer.

10. The method of claim 1, further comprising:
forming a first semiconductor chip structure by dicing the first base wafer into a plurality of first base chips; and
forming a second semiconductor chip structure by dicing the second base wafer into a plurality of second base chips.

11. The method of claim 1, wherein the first portion of the adhesive layer includes:
a mounting region to which the corresponding semiconductor chip is attached; and
a non-mounting region other than the mounting region.

12. The method of claim 11,
wherein the non-mounting region includes a portion extending in a first direction and a portion extending in a second direction perpendicular to the first direction, and
wherein a width of the non-mounting region is in a range of 50 μm to 100 μm.

13. A method of manufacturing a semiconductor device, the method comprising:
forming a plurality of semiconductor chips on a wafer;
sorting the plurality of semiconductor chips into a first semiconductor chip group and a second semiconductor chip group by performing a wafer test on the wafer;
providing a first adhesive tape sheet and a second adhesive tape sheet;
transferring the first semiconductor chip group to the first adhesive tape sheet;
transferring the second semiconductor chip group to the second adhesive tape sheet;
providing a first base wafer and a second base wafer;
separating first semiconductor chips of the first semiconductor chip group from the first adhesive tape sheet;
sequentially stacking the first semiconductor chips on the first base wafer;
separating second semiconductor chips of the second semiconductor chip group from the second adhesive tape sheet; and
sequentially stacking the second semiconductor chips on the second base wafer,
wherein each of the first adhesive tape sheet and the second adhesive tape sheet includes an adhesive layer including a polymer composition including a thixotropic agent.

14. The method of claim 13, wherein the transferring the first semiconductor chip group and the second semiconductor chip group to the first adhesive tape sheet and the second adhesive tape sheet is performed under a first pressing force.

15. The method of claim 14, wherein a viscosity of the adhesive layer decreases under the first pressing force.

16. The method of claim 13, wherein separating the first semiconductor chips of the first semiconductor chip group and the second semiconductor chips of the second semiconductor chip group from the first adhesive tape sheet and the second adhesive tape sheet is performed under a first pulling force.

17. The method of claim 16, wherein a viscosity of the adhesive layer decreases under the first pulling force.

18. The method of claim 16, wherein at least a portion of the adhesive layer is elongated in a vertical direction under the first pulling force.

19. A method of manufacturing a semiconductor device, the method comprising:
sorting a plurality of semiconductor chips into a plurality of grades by performing a wafer test on a wafer on which the plurality of semiconductor chips are formed, the plurality of semiconductor chips including first semiconductor chips of a first grade;
transferring each of the first semiconductor chips onto an adhesive tape sheet; separating the first semiconductor chips from the adhesive tape sheet; and
sequentially stacking the first semiconductor chips on a base wafer,
wherein the adhesive tape sheet includes a thixotropic adhesive layer including a polymer composition including a thixotropic agent, and
wherein a weight ratio of the thixotropic agent relative to the polymer composition is in a range of 1 wt(%) to 5 wt(%).

20. The method of claim 19, wherein the base wafer includes a plurality of preliminary base chips, each of which has a grade same as the first grade.
